(19) United States
(12) Patent Application Publication
(10) Pub. No.: US 2004/0031934 A1
(43) Pub. Date: Feb. 19, 2004

(54) System and method for monitoring ion implantation processing

(76) Inventors: William Mark Hiatt, Eagle, ID (US); Karl E. Mautz, Round Rock, TX (US)

Correspondence Address: MOTOROLA INC, AUSTIN INTELLECTUAL PROPERTY, LAW SECTION, 7700 WEST PARMER LANE MD: TX32/PL02, AUSTIN, TX, 78729

(21) Appl. No.: 10/219,517

(22) Filed: Aug. 15, 2002

(51) Int. Cl. H01J 37/317; H01J 37/244

(52) U.S. Cl. 250/492.21; 250/397

(57) ABSTRACT

A system for monitoring ion implantation processing on a semiconductor wafer (10), comprising a plurality of Faraday cups (12-28, 32) for collecting charge that is not deposited on the wafer (10) during ion implantation processing, means (40) for determining Faraday cups (12-28, 32) that are collecting charge in a particular position of an ion beam (30) relative to the wafer (10) and means (40) for determining the particular ion beam position relative to the wafer (10) on the basis of the Faraday cups (12-28, 32) collecting charge. The present invention further relates to a method of monitoring ion implantation processing.

### FIELD OF THE INVENTION

The present invention generally relates to a system for monitoring ion implantation processing on a semiconductor wafer, and more particularly to a system of monitoring ion implantation processing on a semiconductor wafer using Faraday cups. The present invention further relates to a method of monitoring ion implantation processing on a semiconductor wafer.

### BACKGROUND OF THE INVENTION

Ion implantation is a technique well-known in the art. Ions are accelerated to an energy large enough to cause the ions to penetrate through a surface of a target object. Thereby, the ion is implanted in the object. For example, semiconductor wafers are doped by such a technique.

In order to perform an ion implantation in various regions of a semiconductor wafer, the wafer is usually scanned with respect to the ion beam. In particular due to this feature, it is important to know the position of the wafer relative to the ion beam. To achieve this, prior art techniques use a single Faraday cup to monitor single point implantation beams prior to implanting wafers.

Besides single point implantation beams, ribbon beam technology is employed for implantation processing of semiconductor wafers. Such a ribbon beam, i.e. an ion beam with a shape of, for example, 350 mm×40 mm, is obtained by a particular multipole arrangement. Such an arrangement improves the implantation efficiency, since a scan in a single direction is sufficient to perform an implantation on the whole wafer.

It was already proposed to use multiple Faraday cups in order to determine the ion beam uniformity. An example of such a prior art arrangement is illustrated in FIG. 10. The illustration shows a semiconductor wafer 110 that is placed in front of a primary Faraday cup 134. Adjacent to this primary Faraday cup 134, there are two secondary Faraday cups 136, 138 provided. A ribbon beam 130 is shown in a centered position with respect to the semiconductor wafer 110. In prior art techniques, the primary Faraday cup 134 and the secondary Faraday cups 136, 138 are used to determine the beam uniformity without a wafer on the chuck, i.e. prior to implantation processing. The secondary Faraday cups 136, 138 are also used during implantation processing in order detect instabilities of the ion beam 130 with respect to its position relative to the semiconductor wafer 110.

However, the prior art fails to provide sufficient information concerning the uniformity and the stability of the implant dose during the whole implantation processing. Thus, if instabilities occur during the implantation processing, no measures can be taken in order to stabilize the ion beam. As a result, the production yield is reduced since not all of the wafers are implanted under acceptable conditions.

The present invention seeks to solve the above mentioned problems and to provide a system and a method for monitoring ion implantation processing during the implantation process, thereby providing an improved reliability, an improved implantation quality, and an improved yield.

### BRIEF DESCRIPTION OF THE DRAWINGS

FIG. 1 is a schematic view of a system according to the present invention;

FIG. 2 is a schematic view of a system according to the present invention during implantation processing with an ion beam in a first position;

FIG. 3 is a diagram showing signal intensities I of Faraday cups at different positions x, the ion beam being in a position according to FIG. 2;

FIG. 4 is a schematic view of a system according to the present invention during implantation processing with an ion beam in a second position;

FIG. 5 is a diagram showing signal intensities I of Faraday cups at different positions x, the ion beam being in a position according to FIG. 4;

FIG. 6 is a schematic view of a system according to the present invention during implantation processing with an ion beam in a third position;

FIG. 7 is a diagram showing signal intensities I of Faraday cups at different positions x, the ion beam being in a position according to FIG. 6;

FIG. 8 is a further embodiment of a system according to the present invention;

FIG. 9 is a flow diagram showing a preferred embodiment of a method according to the present invention; and

FIG. 10 is a schematic view of a system according to prior art.

### DETAILED DESCRIPTION OF PREFERRED EMBODIMENTS

According to the invention, a system for monitoring ion implantation processing on a semiconductor wafer 10 is provided, the system comprising

a plurality of Faraday cups 12-28, 32 for collecting charge that is not deposited on the wafer 10 during ion implantation processing,

means 40 for determining Faraday cups 12-28, 32 that are collecting charge in a particular position of an ion beam 30 relative to the wafer 10 and

means 40 for determining the particular ion beam position relative to the wafer 10 on the basis of the Faraday cups 12-28, 32 collecting charge.

According to the invention, a method of monitoring ion implantation processing on a semiconductor wafer 10 is provided, the method comprising the steps of

collecting charge that is not deposited on the wafer 10 during ion implantation processing by a plurality of Faraday cups 12-28, 32,

determining Faraday cups 12-28, 32 that are collecting charge in a particular position of an ion beam 30 relative to the wafer 10 and

determining the particular ion beam position relative to the wafer 10 on the basis of the Faraday cups 12-18, 32 collecting charge.

There are several advantages related to the system and to the method according to the present invention. The new technique provides real-time feedback as to the condition of the wafer 10 as it is processed during implantation. It is possible to verify the condition of the ion beam 30 during the implantation. The feedback minimizes the potential scrap due to beam instability or equipment performance, i.e. instability of a moving stage. The performance of the process can be monitored continuously. Further, data for each implanted wafer 10 can be stored in a database for correlation with probe results. Thus, measures can be taken when deviations from an expected performance are observed.

In particular, it is advantageous to determine an amount of charge collected by the Faraday cups 12-28, 32, in addition to identifying, by which Faraday cup 12-28, 32 charge is collected. The information concerning the amount of charge can be additionally used during monitoring.

Preferably, at least a part of the plurality of Faraday cups 12-28 is at least partially covered by the wafer 10 in ion beam direction. The Faraday cups 12-28, 32 might be located behind the implant station. The cups are used to collect the beam over-shoot, so that information can be processed to determine the quality of the implant in terms of, for example, beam and stage travel and speed.

There are special advantages related to a system and a method, wherein the Faraday cups 12-28 are elongated members that are arranged parallel and at least partially behind the wafer 10. Thus, a square can be provided that is, for example, approximately 25 mm larger then the wafer 10 in x and y directions. As the wafer 10 is passed through the beam 30, the beam overlap would be monitored by the system for beam uniformity and total dose.

In a further design, it is possible to mount the Faraday cups 32 directly to the wafer chuck. This is particularly advantageous with Faraday cups 32 surrounding the wafer processing position. Thereby, a multiplicity of Faraday cups 32 can be provided, resulting in a good resolution. Consequently, the ion beam position can be determined reliably.

If a ribbon beam technology is used, such beam 30 is used with a constant beam width which is maintained through the full scan of the wafer 10. Thus, the position of the ribbon beam 30 can be determined by identifying the Faraday cups 12-28, 32 that collect charge and by determining the amount of charge collected. Also the stability of the ribbon beam 30 can be estimated on the basis of analyzing the Faraday cup information.

The present invention and particular advantages thereof will be further described with respect to the accompanying drawings.

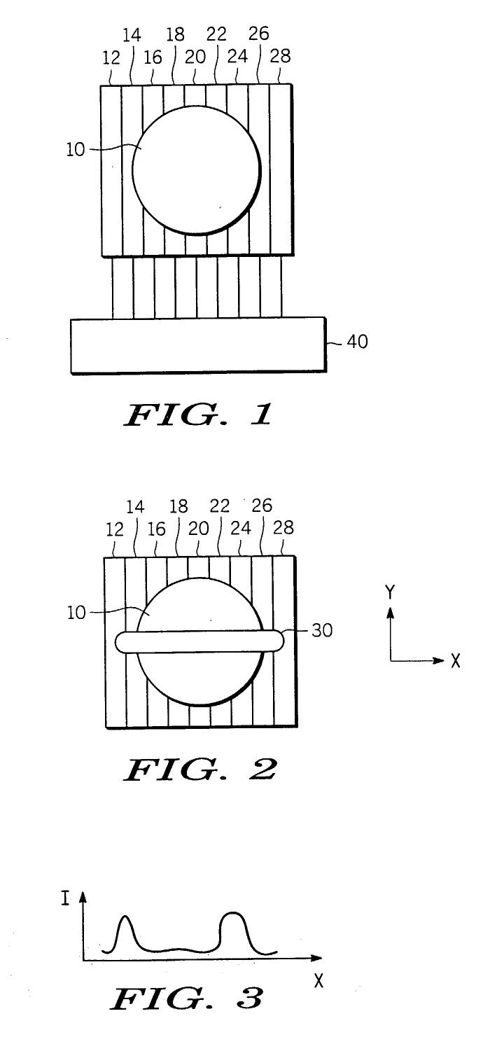

FIG. 1 is a schematic view of a system according to the present invention. Behind a semiconductor wafer 10 a plurality of Faraday cups 12-28 are provided. A part of the Faraday cups 14-26 are partially placed behind the wafer 10. Each of the Faraday cups 12-28 is connected to means 40 for identifying which Faraday-cups are collecting charge. Further, the means 40 are adapted for determining a particular ion beam position on the basis of the Faraday cups 12-28 determined before. The means 40 are also adapted for determining an amount of charge collected by the Faraday cups 12-28.

FIG. 2 is a schematic view of a system according to the present invention during implantation processing with an ion beam 30 in a first position. FIG. 3 is a diagram showing signal intensities I of Faraday cups 12-28 at different positions x, the ion beam being in a position according to FIG. 2. In the centered position of the ion beam 30 that is of the ribbon beam type, with respect to the semiconductor wafer 10, only a small amount of charge is not collected by the wafer 10 but by Faraday cups 12, 14, 26, 28 at the left and at the right of the plurality of Faraday cups 12-28. Thus, the charge distribution, as illustrated in FIG. 3, but not to the same scale, comprises two relatively sharp peaks at the extreme x-positions. Therefore, on the basis of such a charge distribution, it can be determined that the ion beam 30 is well-centered.

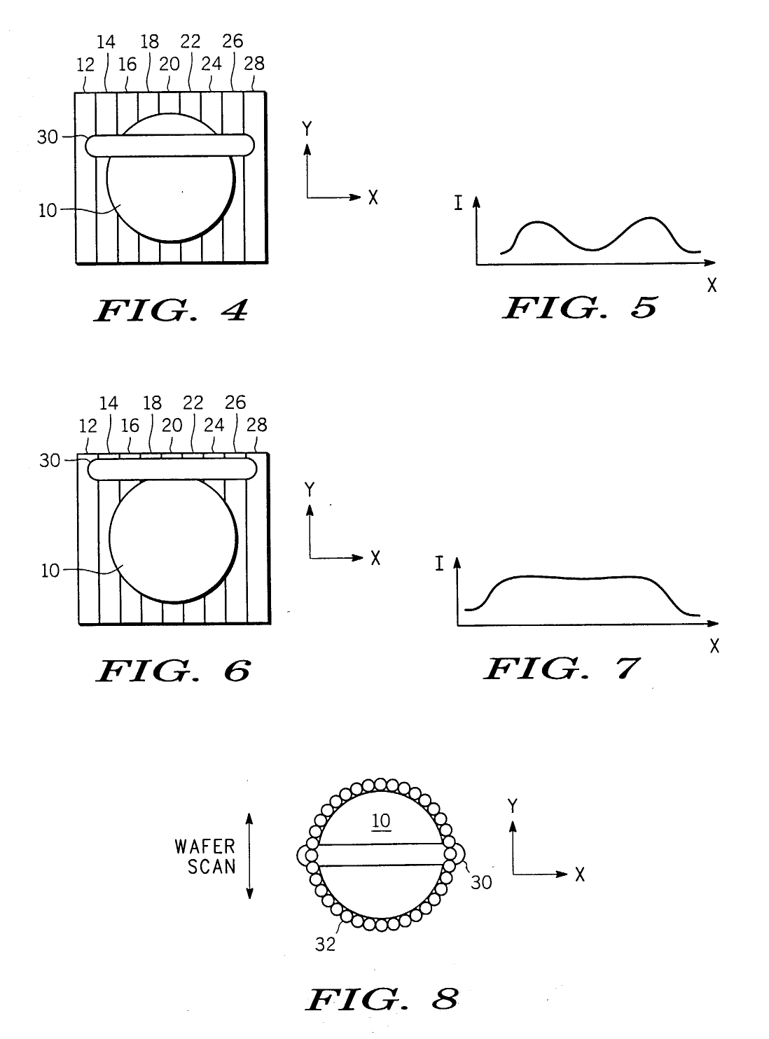

FIG. 4 is a schematic view of a system according to the present invention during implantation processing with an ion beam 30 in a second position. FIG. 5 is a diagram showing signal intensities I of Faraday cups 12-28 at different positions x,the ion beam being in a position according to FIG. 4. In the ion beam position 30 shown in FIG. 4, a larger amount of charge, as compared to FIG. 2, is deposited in Faraday cups near the edge of the Faraday cup arrangement. Thus, the peaks of the charge distribution shown in FIG. 5 are broader (again, FIG. 5 is not to the same scale as FIG. 4).

FIG. 6 is a schematic view of a system according to the present invention during implantation processing with an ion beam in a third position. FIG. 7 is a diagram showing signal intensities I of Faraday cups 12-28 at different positions x, the ion beam being in a position according to FIG. 6. If the ion beam 30 has the position as shown in FIG. 6, an almost uniform charge distribution, as shown in FIG. 7, (again, not to the same scale as FIG. 6), is detected. All of the Faraday cups 12-28 are identified to collect charge, and the amount of charge collected by each Faraday cup 12-28 is comparable. Thus, the charge distribution according to FIG. 7 shows that the beam has reached the edge of the wafer 10 in y-direction and that the beam 30 has a uniform intensity distribution in x-direction.

FIG. 8 is a further embodiment of a system according to the present invention. The Faraday cups 32 are arranged around the position of the wafer 10 and, preferably, mounted directly to the wafer chuck. Due to the large number of Faraday cups 32, the position of the beam 30 can be determined with high accuracy.

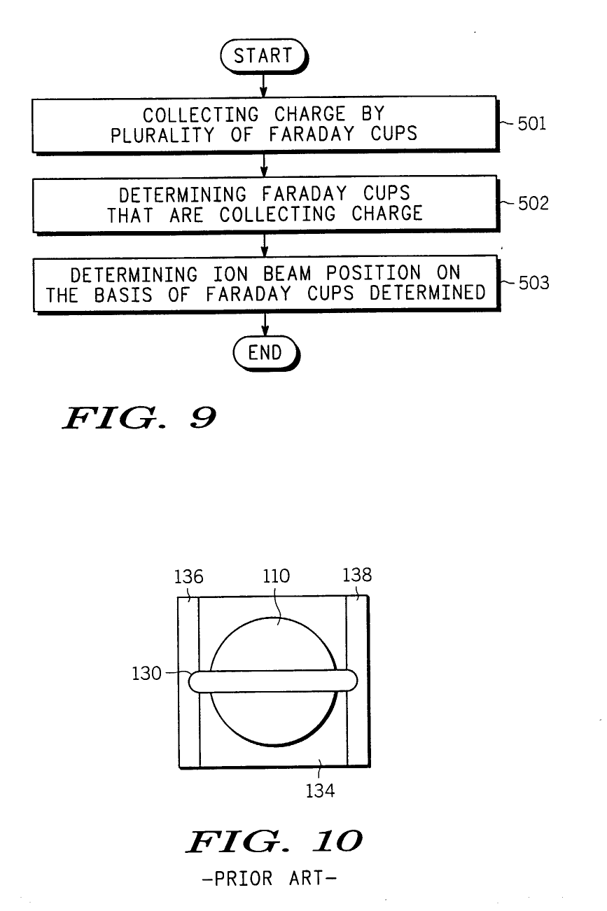

FIG. 9 is a flow diagram showing a preferred embodiment of a method according to the present invention.

After starting the method according to the present invention, in step 501 charge that is not deposited on the semiconductor wafer is collected by a plurality of Faraday cups.

In step 502 it is determined, which Faraday cups are collecting the charge.

In step 503, on the basis of the Faraday cups identified, the ion beam position is determined. Additionally, it is useful to determine the amount of charge collected by the Faraday cups. Thus, it is possible to obtain information concerning beam position, beam uniformity and beam stability.

During ribbon beam scanning of the wafer for ion implantation, the uniformity of the beam, direction of wafer stage travel, including velocity and acceleration can be monitored. This information is used to verify process conditions (settings) and process stability. This data can be tracked using statistical process control (SPC).

After step 503 the method ends.

While the invention has been described in terms of particular structures, devices and methods, those of skill in the art will understand based on the description herein that it is not limited merely to such examples and that the full scope of the invention is properly determined by the claims that follow.

1. A system for monitoring ion implantation processing on a semiconductor wafer, comprising
a plurality of Faraday cups for collecting charge that is not deposited on the wafer during ion implantation processing,
means for determining Faraday cups that are collecting charge in a particular position of an ion beam relative to the wafer and
means for determining the particular ion beam position relative to the wafer on the basis of the Faraday cups collecting charge.

2. The system according to claim 1, further comprising means for determining an amount of charge collected by the Faraday cups collecting charge.

3. The system according to claim 1, wherein at least a part of the plurality of Faraday cups is at least partially covered by the wafer in ion beam direction.

4. The system according to claim 1, wherein
the Faraday cups are longer than a wafer diameter in a first direction perpendicular to the ion beam and the Faraday cups are shorter than a wafer diameter in a second direction perpendicular to the ion beam, thereby providing elongated Faraday cups,
the elongated Faraday cups are arranged in parallel to each other and
at least a part of the plurality of Faraday cups is at least partially covered by the wafer in ion beam direction.

5. The system according to claim 1, wherein the Faraday cups are mounted to a wafer chuck.

6. The system according to claim 1, wherein the Faraday cups are mounted around a wafer processing position.

7. The system according to claim 1, wherein the position of a ribbon beam that is desired to have a constant beam shape is determined.

8. The system according to claim 1, further comprising means for determining an ion beam-stability on the basis of charge collected by the Faraday cups.

9. A method of monitoring ion implantation processing on a semiconductor wafer, comprising the steps of
collecting charge that is not deposited in the wafer during ion implantation processing by a plurality of Faraday cups,
determining Faraday cups that are collecting charge in a particular position of an ion beam relative to the wafer and
determining the particular ion beam position relative to the wafer on the basis of the Faraday cups collecting charge.

10. The method according to claim 9, further comprising determining an amount of charge collected by the Faraday cups collecting charge.

11. The method according to claim 9, wherein at least a part of the plurality of Faraday cups is at least partially covered-by the wafer in ion beam direction.

12. The method according to claim 9, wherein
the Faraday cups are longer than a wafer diameter in a first direction perpendicular to the ion beam and the Faraday cups are shorter than a wafer diameter in a second direction perpendicular to the ion beam, thereby providing elongated Faraday cups,
the elongated Faraday cups are arranged in parallel to each other and
at least a part of the plurality of Faraday cups is at least partially covered by the wafer in ion beam direction.

13. The method according to claim 9, wherein the Faraday cups are mounted to a wafer chuck.

14. The method according to claim 9, wherein the Faraday cups are mounted around a wafer processing position.

15. The method according to claim 9, wherein the position of a ribbon beam that is desired to have a constant beam shape is determined.

16. The method according to claim 9, further comprising determining an ion beam stability on the basis of charge collected by the Faraday cups.
